(19) United States
(12) Patent Application Publication
(10) Pub. No.: US 2013/0064393 A1
(43) Pub. Date: Mar. 14, 2013

(54) SOUND REPRODUCING DEVICE AND SOUND REPRODUCING METHOD

(71) Applicants: Satoshi Yamazaki, Nagano (JP); Makoto Kawabata, Tokyo (JP); Shinya Haraguchi, Tokyo (JP)

(72) Inventors: Satoshi Yamazaki, Nagano (JP); Makoto Kawabata, Tokyo (JP); Shinya Haraguchi, Tokyo (JP)

(73) Assignee: SONY CORPORATION, Tokyo (JP)

(21) Appl. No.: 13/603,744

(22) Filed: Sep. 5, 2012

(30) Foreign Application Priority Data
Sep. 12, 2011 (JP) 2011-198141

(51) Int. Cl. H03G 3/20; H03G 3/00

(52) U.S. Cl. 381/105; 381/104

(57) ABSTRACT

A sound reproducing device includes: a wireless communication unit receiving an audio signal and outputting the audio signal by wireless communication; an audio reproducing unit including speakers reproducing the audio signal; and a control unit controlling on/off of a first power supply with respect to the audio reproducing unit, wherein the control unit turns on the first power supply when receiving a connection notification from the wireless communication unit in a standby state in which a second power supply with respect to the wireless communication unit and the control unit is on and allows the audio reproducing unit to reproduce the audio signal from the wireless communication unit, and the control unit turns off the first power supply when receiving a cutoff notification from the wireless communication unit and allows the reproduction of the audio signal from the wireless communication unit to be stopped.

### BACKGROUND OF THE INVENTION

The present disclosure relates to a sound reproducing device connected to a portable music reproducing device such as a digital audio player by wireless communication and reproducing an audio signal reproduced by the portable music reproducing device, and a sound reproducing method.

In related art, portable music reproducing devices having a wireless communication function such as Bluetooth (trademark) are commercialized, which are, for example, a digital audio player, a smartphone, a portable personal computer and the like. A configuration in which a wireless module for Bluetooth is housed in an electronic device, a configuration in which the wireless module is attachable as an adapter and the like are known. Music reproduced by, for example, the portable music reproducing device can be listened to by a wireless headset in the outdoors. Then, in the house, music reproduced by the portable music reproducing device can be listened to by the sound reproducing device (a so-called wireless speaker system).

In the case where an audio signal from the portable music reproducing device is reproduced by the sound reproducing device, it is necessary to turn on the power of the sound reproducing device and set an input selector in a state of selecting the portable music reproducing device (Bluetooth device). Accordingly, there is a problem that convenience of wireless communication is reduced as it is necessary to go to a place of the sound reproducing device for operating a switch of the system. Moreover, there is a problem that wasteful power consumption occurs as the power of the sound reproducing device is constantly on.

In JP-A-2005-310287 (Patent Document 1), there is disclosed that audio is outputted from a stationary device without placing a portable terminal on the stationary device. In JP-A-2002-300060 (Patent Document 2), there is disclosed that, when a user moves into a room or a car while music is reproduced by a portable audio device, the same music is continuously reproduced in a floorstanding audio device or a car-mounted audio device without replacement work of a recording medium.

### BRIEF SUMMARY OF THE INVENTION

In Patent Document 1, a communication path of an optical remote control signal and a wireless (radio) communication path for transmitting an audio signal are provided between the portable terminal and the stationary device. When a remote switch is pressed in the portable terminal, a mode of outputting audio from headphones connected to the portable terminal and a remote mode of outputting audio from the stationary device are determined. In the remote mode, a signal for turning on the power of the stationary device is transmitted from the portable terminal to the stationary device through the optical communication path.

It is necessary to operate both a mode switch and a remote switch in the portable terminal in order to turn on the power of the stationary device and reproduce music by the stationary device in the system disclosed in Patent Document 1. Moreover, it is necessary that the user know the meaning in operation of the remote switch. There is a problem that operationality is not excellent in view of the above.

In the description of Patent Document 2, there is disclosed a point where the power of a data receiving device is turned on to reproduce music by the data receiving device. However, there is no description of a case where the power of the data receiving device is turned off when the reproduction of music by the data receiving device is finished. In the case where a power switch of the data receiving device is operated for turning off the power of the data receiving device, it is necessary to go to a separate place where the data receiving device is located, which may reduce the convenience in wireless communication.

In view of the above, it is desirable to provide a sound reproducing device with good operationality, in which it is not necessary that the user carrying the portable music reproducing device performs on-operation and off-operation of a power switch.

An embodiment of the present disclosure is directed to a sound reproducing device including a wireless communication unit receiving an audio signal and outputting the audio signal by wireless communication, an audio reproducing unit including speakers reproducing the audio signal, and a control unit controlling on/off of a first power supply with respect to the audio reproducing unit, in which the control unit turns on the first power supply when receiving a connection notification from the wireless communication unit in a standby state in which a second power supply with respect to the wireless communication unit and the control unit is on and allows the audio reproducing unit to reproduce the audio signal from the wireless communication unit, and the control unit turns off the first power supply when receiving a cutoff notification from the wireless communication unit and allows the reproduction of the audio signal from the wireless communication unit to be stopped.

Another embodiment of the present disclosure is directed to a sound reproducing method including receiving an audio signal and outputting the audio signal by wireless communication of a wireless communication unit, reproducing the audio signal by an audio reproducing unit, and controlling on/off of a first power supply with respect to the audio reproducing unit by a control unit, in which the control unit turns on the first power supply when receiving a connection notification from the wireless communication unit in a standby state in which a second power supply with respect to the wireless communication unit and the control unit is on and allows the audio reproducing unit to reproduce the audio signal from the wireless communication unit, and the control unit turns off the first power supply when receiving a cutoff notification from the wireless communication unit and allows the reproduction of the audio signal from the wireless communication unit to be stopped.

According to the embodiments of the present disclosure, in the case where the audio signal reproduced by the portable music reproducing device in hand is reproduced by the sound reproducing device at a separate place, it is possible to control on/off of the power without operating the power switch of the sound reproducing device.

### BRIEF DESCRIPTION OF THE DRAWINGS

FIG. 1 is a perspective view showing an appearance of a sound reproducing device according to an embodiment of the present disclosure;

FIG. 2 is a block diagram showing the sound reproducing device according to the embodiment of the present disclosure;

FIG. 3 is a flowchart used for explaining operations of the sound reproducing device according to the embodiment of the present disclosure; and

FIG. 4 is a flowchart used for explaining operations of the sound reproducing device according to the embodiment of the present disclosure.

### DETAILED DESCRIPTION

Embodiments explained below are preferred specific examples of the present disclosure, in which various technically-preferable limitations are imposed, however, the scope of the present disclosure is not limited to these embodiments as long as there is no particular description of limitation in the following explanation.

### Example of Sound Reproducing Device

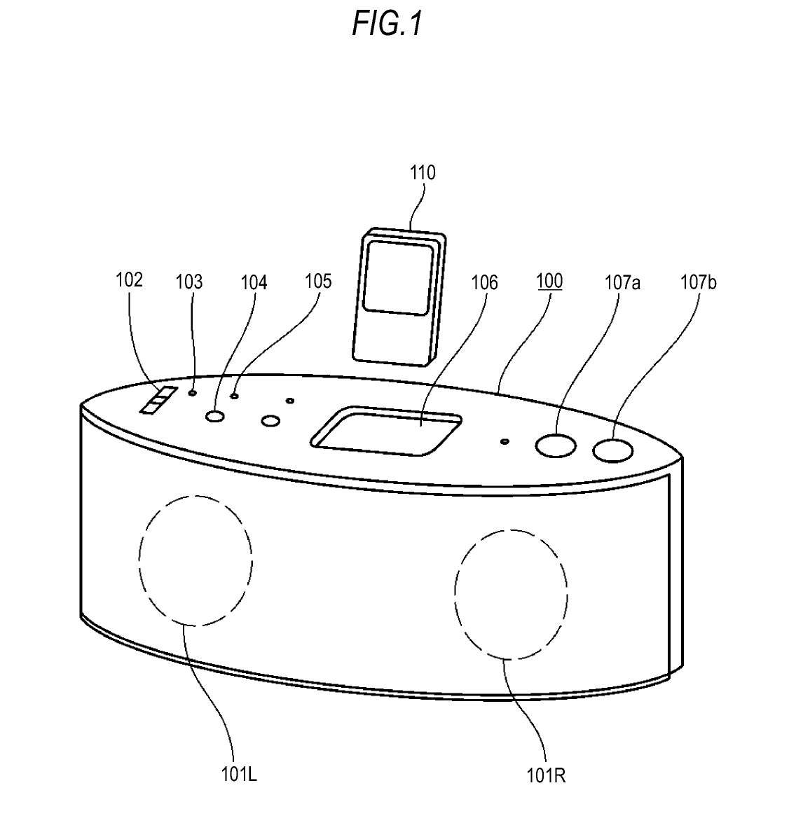

An embodiment of the present disclosure will be explained. An example of a sound reproducing device to which the present disclosure can be applied will be explained with reference to FIG. 1. A sound reproducing device 100 is provided with a left-channel speaker 101L and a right-channel speaker 101R in a casing. The present disclosure can be also applied to a structure in which speakers are separated and the speakers and a power amplifier are connected by a speaker cable.

Operation switches are provided on an upper surface of the casing. 102 denotes a power switch, which can switch among three kinds of states of the power, namely, on, off and waiting (so-called stand-by). 103 denotes a power lamp indicating states of the power. As described later, on/off of a first power supply with respect to an audio reproducing unit and on/off of a second power supply with respect to a Bluetooth module as a wireless communication unit and a control unit (CPU) can be independently controlled.

In an on-position of the power switch 102, the first and second power supplies are both in the on-state. In an off-position of the power switch 102, the first and second power supplies are both in the off-state. In a standby position of the power switch 102, the first power supply is in the off-state and the second power supply is in the on-state. Accordingly, the Bluetooth module is in a waiting state and the control unit is during waiting processing in the standby state.

104 denotes a line-input selection button and 105 denotes a line-input lamp indicating a line-input selection state. A connection terminal for line input is provided on a back surface of the casing. A concave portion 106 denotes a fixing portion (dock) to and from which a portable music reproducing device 110 is fixed and removed. A (not shown) plug forming a connection port is provided on a bottom of the concave portion 106 for fixing.

The portable music reproducing device 110 includes operation buttons, a liquid crystal display unit and so on, recording music data in memory media such as a memory card, a hard disc and an internal memory and capable of reproducing music data from the memory media. The sound reproducing device 100 and the portable music reproducing device 110 can be connected to each other by a port as well as by wireless connection in Bluetooth. 107a denotes a volume increase button and 107b denotes a volume decrease button.

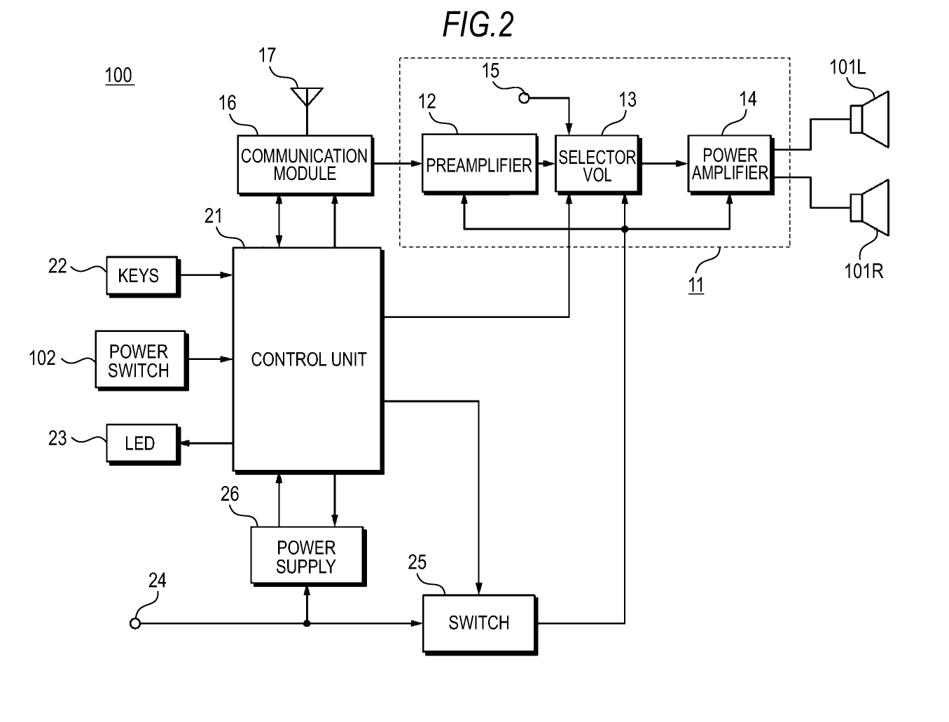

An electrical configuration of the sound reproducing device 100 will be explained with reference to FIG. 2. The audio signal is supplied to the speakers 101L and 101R from the audio reproducing unit 11. The audio reproducing unit 11 is configured by sequentially connecting a preamplifier 12, a selector and volume control unit 13 and a power amplifier 14. The power is supplied as the first power supply to the preamplifier 12, the selector and volume control unit 13 and the power amplifier 14 of the audio reproducing unit 11 through a switch 25.

An audio signal outputted from a communication module 16 is inputted into the audio reproducing unit 11. The communication module 16 is an IC circuit for performing communication of Bluetooth. For example, a wireless communication signal from the portable music reproducing device is received by an antenna 17 and subjected to processing such as modulation in the communication module 16 to thereby generate the audio signal. An audio signal from a line input terminal 15 is supplied to the selector and audio control unit 13. In the selector and audio control unit 13, one of the audio signal from the communication module 16 and the line-input audio signal from the input terminal 15 is selectively reproduced according to operation of the line-input selection button 104.

The control unit 21 is a microcomputer including a CPU (Central Processing Unit), a RAM (Random Access Memory), a flash ROM (Read Only Memory), a clock circuit and so on, controlling respective units of the sound reproducing device according to the embodiment. For example, the control unit 21 generates control signals with respect to the selector and volume control unit 13, the communication module 16, the switch 25 and a power supply circuit 26. Outputs of various keys 22 and the power switch 102 described above are supplied to the control unit 21, and drive signals with respect to the LED (Light Emitting Diode) 23 such as the power lamp 103 are supplied from the control unit 21.

Input DC power generated from commercial power is supplied to a DC input terminal 24. The input DC power as the first power supply is supplied to the preamplifier 12, the selector and volume control unit 13 and the power amplifier 14 in the audio reproducing unit 11 through the switch 25 in the on-state. The second power supply generated from the input DC power by the power supply circuit 26 is supplied to the control unit 21. When the power switch 102 is in the power-on position and in the standby position, the power is supplied from the power supply circuit 26. It is also preferable that different powers are supplied to the control 21 between the power-on and standby positions for saving power.

The control unit 21 and the communication module 16 are bi-directionally connected, and information indicating communication states from the communication module 16 is supplied to the control unit 21. The control unit 21 outputs power control signals in accordance with the state of the power switch 102. The power control signals are supplied to the switch 25 and the power supply circuit 26. In the power-off state, the switch 25 is turned off and power supply with respect to the audio reproducing unit 11 is switched off.

In the power-on state, the switch 25 is turned on and power supply with respect to the audio reproducing unit 11 is switched on. DC power from the power supply circuit 26 is supplied to the control unit 21. In the power standby state, the switch 25 is turned off and the power from the power supply circuit 26 is supplied to the control unit 21. As power supply with respect to the audio reproducing unit 11 is off in the standby state, power consumption can be reduced as compared with the power on state. Additionally, in the power-off state, power supply with respect to both the audio reproducing unit 11 and the control unit 21 is off. Moreover, the control unit 21 generates control signals with respect to respective units of the sound reproducing device.

It is possible to add a tuner function of receiving radio broadcasting, a CD reproducing function of reproducing CDs and so on to the sound reproducing device according to the embodiment of the present disclosure.

### Bluetooth Communication

Bluetooth is used for an application of performing wireless communication of character information, audio information and so on between portable electronic devices at relatively low speed by a spread spectrum technology using radio waves in 2.4 GHz band (ISM band). In Bluetooth, the radio wave band of 2.4 GHz is divided into 79 frequency channels to perform frequency hopping which changes frequencies to be used at random, thereby performing wireless communication of 24 Mbps at maximum with respect to Bluetooth-equipped devices in near field (approximately 10 to 100 m).

In the present embodiment, communication is performed between the portable terminal equipped with Bluetooth such as the portable music reproducing device and the sound reproducing device, and a reproduced audio signal of the portable music reproducing device is reproduced by the sound reproducing device. As Bluetooth is used for communication of various devices, protocols are designed according to the type of devices. More specifically, both the portable music reproducing device and the sound reproducing device are formed to comply with A2DP (Advanced Audio Distribution Profile) and AVRCP (Audio/Video Remote Control Profile).

A2DP is a profile for transmitting audio to headphones (earphones) with receivers, capable of transmitting audio in stereo and reproducing audio with high quality, which is different from HSP (Headset Profile)/HFP (Hands-Free Profile). AVRCP is a protocol for realizing a remote control function of AV devices. Volume control of the sound reproducing device can be performed by the portable music reproducing device using AVRCP.

It is necessary to perform pairing between the portable music reproducing device and the sound reproducing device in order to perform wireless communication by Bluetooth (hereinafter appropriately referred to as Bluetooth communication). Both devices can recognize each other's devices respectively and can register information of each other's devices in volatile memories. It is normally necessary to perform pairing once.

Procedures of the pairing are as follows.

The portable music reproducing device and the sound reproducing device are put at a distance within 1 m from each other.

The sound reproducing device is put into a pairing mode.

A menu item of Bluetooth pairing is selected by operating a menu of the portable music reproducing device. A list of devices which can be paired is displayed on a display unit.

The sound reproducing device is selected from the list and the selection is determined.

When input of a passkey is requested, a passkey (numerals) is inputted and determined. Accordingly, the passkey is exchanged between the portable music reproducing device and the sound reproducing device and the pairing is completed.

When the pairing is completed, the portable music reproducing device and the sound reproducing device are ready to perform Bluetooth communication. In order to reproduce music reproduced by the portable music reproducing device in the sound reproducing device, the portable music reproducing device starts reproduction of music by performing Bluetooth connection. The Bluetooth connection actually enables communication in the state where the portable music reproducing device and the sound reproducing device recognize each other's devices and in the Bluetooth connected state. The state of Bluetooth connection is displayed by a Bluetooth button. The sound reproducing device is also provided with a lamp (which doubles as the power lamp) for displaying the communication state.

In related art, it is necessary to allow the power switch of the sound reproducing device to be on (namely, a standby state of Bluetooth connection) in advance for connecting Bluetooth, therefore, it is necessary to go to a separate place where the sound reproducing device is located, which reduces the convenience. It is not necessary to operate the power switch by allowing the sound reproducing device to be in the standby state in the embodiment of the present disclosure. The standby state is a state of waiting for Bluetooth connection, which can reduce power consumption as compared with the power-on state.

For example, two kinds of operation methods are prepared for performing Bluetooth connection by operating the portable music reproducing device. In the first method, the Bluetooth mode is selected by operating the menu of the portable music reproducing device and the sound reproducing device is selected from the list of Bluetooth devices to determine the selection. In the second method, the sound reproducing device is set as the Bluetooth device to be preferentially connected in plural Bluetooth devices to which pairing has been performed, then, Bluetooth connection is performed only by pressing the Bluetooth button.

When the Bluetooth connection is completed in the above manner and the portable music reproducing device starts reproducing operation, an audio signal is transmitted to the sound reproducing device by Bluetooth communication and reproduced by the speakers 101L and 101R. The Bluetooth connection is maintained even when the audio signal is not reproduced, and the mode is moved to a low-power consumption mode according to need.

Moreover, in order to cut off the Bluetooth connection, a menu item for turning off Bluetooth is selected from Bluetooth modes, and the selection is determined. Besides, the Bluetooth connection is also cut off by turning off the power of the portable music reproducing device. Naturally, the Bluetooth connection is also cut off by turning off the power of the sound reproducing device.

The cutoff processing is intentionally performed by the user, which will be referred to as a normal cutoff. When the normal cutoff is performed, the cutoff is notified to the control unit 21 from the communication module 16 of the sound reproducing device. On the other hand, the Bluetooth connection may be cut off even when the user does not intend to cut off the connection. For example, when the user moves out of a reaching range of communication such as to another room while the user carries the portable music reproducing device, it is difficult to receive a Bluetooth signal itself by the antenna 17. Such cutoff is referred to as an abnormal cutoff. The abnormal cutoff is notified to the control unit 21 from the communication module 16.

### Operations of Embodiment

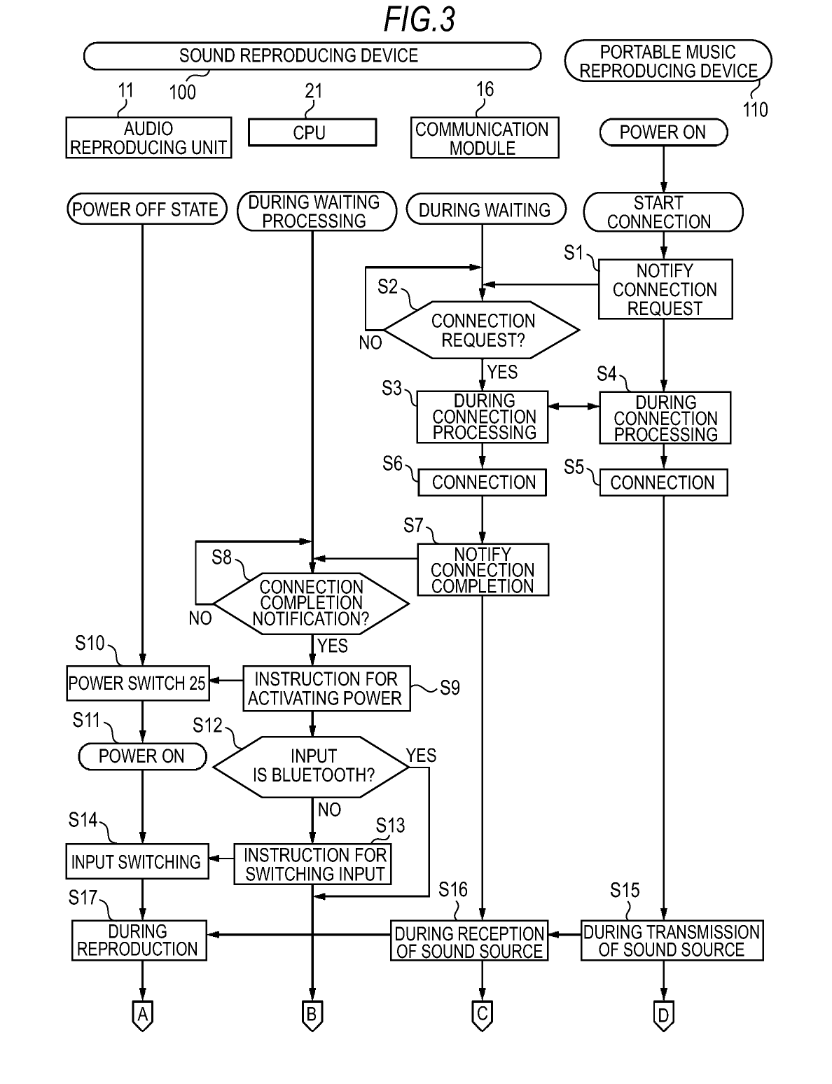

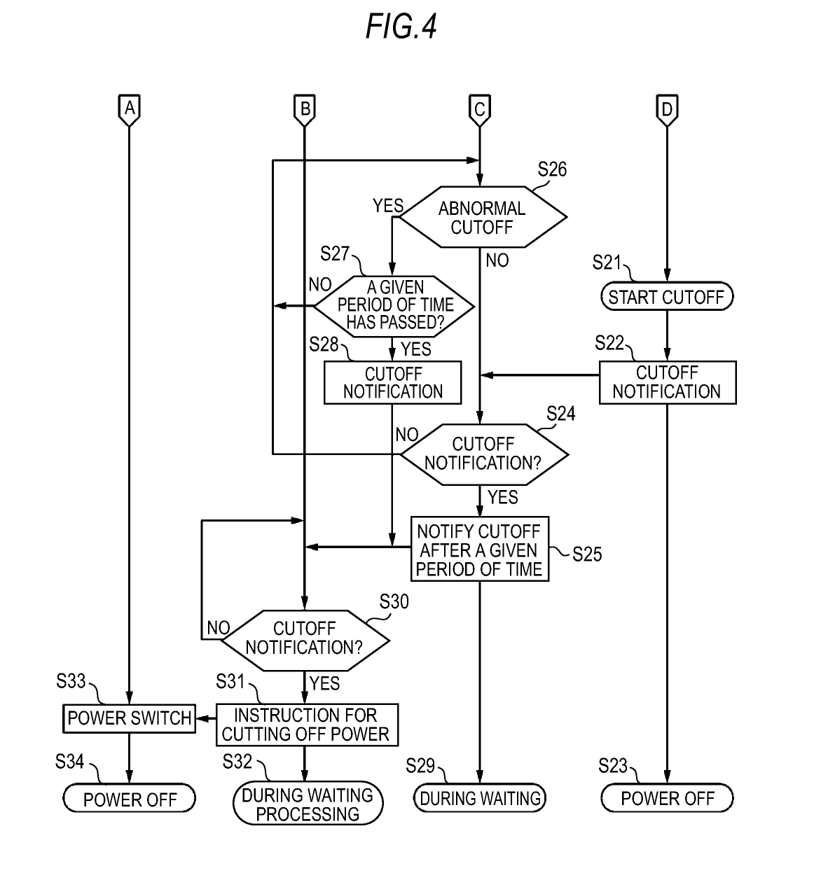

Operations of the embodiment of the present disclosure will be explained with reference to flowcharts of FIG. 3 and FIG. 4. FIG. 3 and FIG. 4 originally form one flowchart, however, the flowchart is divided into two drawings under constraint of drawing space. Connection points between FIG. 3 and FIG. 4 are represented as characters A to D.

Respective processing of the audio reproducing unit 11, the control unit (CPU) 21 and the communication module 16 of the sound reproducing device 100 as well as processing of the portable music reproducing device 110 are shown. The pairing between the sound reproducing device 100 and the portable music reproducing device 110 has been already completed. The first state of the sound reproducing device 100 is the standby state. That is, the power supply of the audio reproducing unit 11 is off, the control unit 21 is in the waiting processing state and the communication module 16 is in the waiting state.

The power of the portable music reproducing device 110 is turned on and the above-described processing of starting connection is performed. A connection request is notified from the portable music reproducing device 110 (Step S1). The communication module 16 determines existence of the connection request as the module is in the waiting state (Step S2). On receiving the notification of the connection request from the portable music reproducing device 110, the portable music reproducing device 110 and the communication module 16 performs connection processing (Steps S3 and S4).

When the connection processing is normally performed, Bluetooth connection state is established (Steps S5 and S6). The communication module 16 notifies the control unit 21 of connection completion (Step S7). The control unit 21 determines existence of notification of connection completion (Step S8).

When the control unit 21 receives the notification of connection completion from the communication module 16, the determination result of Step S8 is affirmative, and an instruction for activating the power is issued in Step S9. The switch 25 is turned on (Step S10) by the instruction for activating the power, the audio reproducing unit 11 becomes in the power-on state (Step S11).

The control unit 21 determines whether the input is Bluetooth or not in Step S12. When it is determined that audio input (line input) other than Bluetooth is selected, the control unit 21 issues an instruction for switching input in Step S13. The instruction for switching input is supplied to the selector and volume control unit 13 from the control unit 21, thereby performing control so that Bluetooth (output of the communication module 16) is selected as the audio input (Step S14). Accordingly, it is possible to perform control so that Bluetooth is selected as input without operating the input changeover switch of the sound reproducing device 100 placed at a separate place.

Then, when a reproducing operation is started in the portable music reproducing device 110, an audio signal can be reproduced by the sound reproducing device 100 through Bluetooth communication from the portable music reproducing device 110. The operation is represented by “during transmission of sound source” (Step S15) in the portable music reproducing device 110, “during reception of sound source” (Step S16) in the communication module 16 and “during reproduction” (Step S17) in the audio reproducing unit 11.

Furthermore, explanation will be made with reference to the flowchart of FIG. 4. The above-described cutoff operation of Bluetooth communication is performed in the portable music reproducing device 110 and the cutoff processing is started (Step S21). A cutoff notification is issued (Step S22). Such cutoff is referred to as the normal cutoff. Then, the power of the portable music reproducing device 110 is turned off (Step S23).

The communication module 16 determines existence of the cutoff notification as shown in Step S24. When receiving the cutoff notification from the portable music reproducing device 110, the determination result of Step S24 is affirmative and the cutoff notification with respect to the control unit 21 is issued after a given period of time (Step S25). After that, the communication module 16 becomes in the waiting state (Step S29). A given period of time is, for example, 1 minute. The given period of time is not fixed, and any of plural periods of time may be set according to user settings and so on. As the normal cutoff is an intended cutoff occurring when the portable music reproducing device 110 is operated, the cutoff processing may be started immediately without waiting for a lapse of time.

In addition to the normal cutoff by the operation to start cutting off in the portable music reproducing device 110, a Bluetooth signal is suddenly stopped in the case where the user goes out of the room while carrying the portable music reproducing device 110 as the portable music reproducing device 110 is positioned out of a reaching range of radio waves. The Bluetooth communication ends due to unintended extinction of the Bluetooth signal. Such cutoff is referred to as the abnormal cutoff.

The communication module 16 determines existence of the abnormal cutoff (Step S26). When the abnormal cutoff occurs, the determination result of Step S26 is affirmative and whether the abnormal cutoff has continued for a given period of time or not is determined in Step S27. When the abnormal cutoff has continued for more than the given period of time, the determination result of Step S27 is affirmative and the cutoff notification with respect to the control unit 21 is issued (Step S28). The given period of time is not fixed and any of plural periods of time may be set according to user settings and so on.

A length of time from the reception of the above cutoff notification to the notification of cutoff with respect to the control unit 21 and a length of time for determining the period of abnormal cutoff can be set to be the same or appropriately set separately. Moreover, these determinations of time are performed in the communication module 16, however, it is also possible to perform determinations by the CPU in the control unit 21. Furthermore, when the communication module 16 can notify the control unit 21 of the cutout so as to discriminate between the normal cutoff and the abnormal cutoff, the determination of time with respect to respective cutouts can be set separately. On the other hand, when it is difficult that the communication module 16 discriminates between the normal cutoff and the abnormal cutoff, the determination of time with respect to both cutouts are set to be the same.

In Step S30, as the control unit 21 determines existence of cutoff notification, the determination result of Step S30 is affirmative when the cutoff is notified in Step S25 (normal cutoff) or Step S28 (abnormal cutoff). The control unit 21 issues an instruction for cutting off the power in Step S31. After that, the control unit 21 becomes in the waiting processing state (Step S32). The switch 25 is turned off according to the instruction for cutting out the power issued by the control unit 21 (Step S33), the power supply with respect to the audio reproducing unit 11 is turned off (Step S34).

As described above, according to the embodiment of the present disclosure, when the connection with respect to the portable music reproducing device 110 is completed, the power supply with respect to the audio reproducing unit 11 is turned on, and music reproduced by the portable music reproducing device 110 can be reproduced by speakers. Therefore, as it is not necessary to go to a separate place where the sound reproducing device is located for turning on the power supply, operationality can be improved. Additionally, when the operation of cutting out the communication is performed in the portable music reproducing device 110, the power supply to the audio reproducing unit 11 is turned off. Furthermore, when user moves to another room while carrying the portable music reproducing device 110, the abnormal cutout occurs. Also in this case, the power supply to the audio reproducing unit 110 can be turned off. Therefore, it is not necessary to go to a separate place where the sound reproducing device 100 is located, which improves operationality as well as prevents wasteful power consumption.

The present disclosure may be implemented as the following configurations.

(1) A sound reproducing device including

a wireless communication unit receiving an audio signal and outputting the audio signal by wireless communication,

an audio reproducing unit including speakers reproducing the audio signal, and

a control unit controlling on/off of a first power supply with respect to the audio reproducing unit,

in which the control unit turns on the first power supply when receiving a connection notification from the wireless communication unit in a standby state in which a second power supply with respect to the wireless communication unit and the control unit is on and allows the audio reproducing unit to reproduce the audio signal from the wireless communication unit, and

the control unit turns off the first power supply when receiving a cutoff notification from the wireless communication unit and allows the reproduction of the audio signal from the wireless communication unit to be stopped.

(2) The sound reproducing device described in the above (1),

in which the control unit turns off the first power supply when receiving a notification of cutting off a wireless signal from the wireless communication unit and a period of the cutoff exceeds a given period of time.

(3) The sound reproducing device described in the above (1) or (2),

in which a length of the given period of time can be set.

(4) The sound reproducing device described in any one of the above (1) to (3),

in which the audio reproducing unit includes a selection unit selecting another audio signal other than the audio signal received from the wireless communication unit, and

the control unit controls the selection unit to select the audio signal received from the wireless communication unit when receiving the connection notification.

(5) The sound reproducing device described in any one of the above (1) to (4),

in which sound volume of the reproduced audio signal is remotely controlled by the wireless communication.

(6) A sound reproducing method including

receiving an audio signal and outputting the audio signal by wireless communication of a wireless communication unit,

reproducing the audio signal by an audio reproducing unit, and

controlling on/off of a first power supply with respect to the audio reproducing unit by a control unit,

in which the control unit turns on the first power supply when receiving a connection notification from the wireless communication unit in a standby state in which a second power supply with respect to the wireless communication unit and the control unit is on and allows the audio reproducing unit to reproduce the audio signal from the wireless communication unit, and

the control unit turns off the first power supply when receiving a cutoff notification from the wireless communication unit and allows the reproduction of the audio signal from the wireless communication unit to be stopped.

### Modification Example

The embodiments of the present disclosure have been specifically explained as the above, however, the present disclosure is not limited to the above respective embodiments and various modifications may occur based on the technical spirit of the present disclosure. For example, the operation method of cutting off communication in the portable music reproducing device in the above embodiment is just an example, and other methods can be applied. It is also preferable to use communication systems other than Bluetooth.

The present disclosure contains subject matter related to that disclosed in Japanese Priority Patent Application JP 2011-198141 filed in the Japan Patent Office on Sep. 12, 2011, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

1. A sound reproducing device comprising:
a wireless communication unit receiving an audio signal and outputting the audio signal by wireless communication;
an audio reproducing unit including speakers reproducing the audio signal; and
a control unit controlling on/off of a first power supply with respect to the audio reproducing unit,
wherein the control unit turns on the first power supply when receiving a connection notification from the wireless communication unit in a standby state in which a second power supply with respect to the wireless communication unit and the control unit is on and allows the audio reproducing unit to reproduce the audio signal from the wireless communication unit, and
the control unit turns off the first power supply when receiving a cutoff notification from the wireless communication unit and allows the reproduction of the audio signal from the wireless communication unit to be stopped.

2. The sound reproducing device according to claim 1,
wherein the control unit turns off the first power supply when receiving a notification of cutting off a wireless signal from the wireless communication unit and a period of the cutoff exceeds a given period of time.

3. The sound reproducing device according to claim 1,
wherein a length of the given period of time can be set.

4. The sound reproducing device according to claim 1,
wherein the audio reproducing unit includes a selection unit selecting another audio signal other than the audio signal received from the wireless communication unit, and
the control unit controls the selection unit to select the audio signal received from the wireless communication unit when receiving the connection notification.

5. The sound reproducing device according to claim 1,
wherein sound volume of the reproduced audio signal is remotely controlled by the wireless communication.

6. A sound reproducing method comprising:
receiving an audio signal and outputting the audio signal by wireless communication of a wireless communication unit;
reproducing the audio signal by an audio reproducing unit; and
controlling on/off of a first power supply with respect to the audio reproducing unit by a control unit,
wherein the control unit turns on the first power supply when receiving a connection notification from the wireless communication unit in a standby state in which a second power supply with respect to the wireless communication unit and the control unit is on and allows the audio reproducing unit to reproduce the audio signal from the wireless communication unit, and
the control unit turns off the first power supply when receiving a cutoff notification from the wireless communication unit and allows the reproduction of the audio signal from the wireless communication unit to be stopped.
